(19) United States
(12) Patent Application Publication
(10) Pub. No.: US 2022/0263163 A1
(43) Pub. Date: Aug. 18, 2022

(54) FLOW GUIDING DEVICE

(71) Applicant: Mahle International GmbH, Stuttgart (DE)

(72) Inventors: Heiko Neff, Auenwald (DE); Carolin Vesenmaier, Rottenburg (DE)

(21) Appl. No.: 17/672,036

(22) Filed: Feb. 15, 2022

(30) Foreign Application Priority Data
Feb. 15, 2021 (DE) 10 2021 201 399.6

(51) Int. Cl. H01M 10/6568; H05K 1/18; H05K 1/02; H01M 10/613; H01M 10/6556; H01M 10/667; H01M 10/625; B60L 58/26

(52) U.S. Cl. CPC H01M 10/6568; H05K 1/181; H05K 1/0203; H01M 10/613; H01M 2220/20; H01M 10/667; H01M 10/625; B60L 58/26; H05K 2201/10037; H01M 10/6556

(57) ABSTRACT

The invention relates to a flow guiding device (1) for guiding a cooling fluid for a battery module. The flow guiding device (1) comprises a base plate (2), on the surface of which at least one electronic component (4) for electrically connecting the flow guiding device (1) to the battery module is arranged, and at least one flow guiding element (3) which projects from the surface of the base plate (2) and at least partially delimits a fluid path (5) for the cooling fluid to flow through.

### CROSS-REFERENCE TO RELATED APPLICATION

This application claims priority to German Patent Application No. DE 102021201399.6, filed on Feb. 15, 2021, the contents of which is hereby incorporated by reference in its entirety

### TECHNICAL FIELD

The present invention relates to a flow guiding device for guiding a cooling fluid for a battery module. Furthermore, the invention relates to a battery module, in particular for a motor vehicle, having such a flow guiding device.

### BACKGROUND

In order to achieve greater acceptance of electric or hybrid vehicles among end customers, it is particularly important that the required recharging time span until a battery module of an electric or hybrid vehicle is fully recharged is as short as possible. It is possible to shorten the recharging time span, for example, by increasing the electrical power supplied via a corresponding recharging station. As a result of this increased electrical power, the battery module experiences an increased thermal load, so that appropriate cooling of the battery module is required during the charging process. Even when the electric or hybrid vehicle is being driven, the battery module must be cooled as required in order to operate battery cells and electronic components of the battery module in particular at optimum operating temperatures and thus achieve improved performance and a longer service life for the battery module.

Direct cooling is suitable for dissipating such thermal loads on the battery module, in which a cooling fluid flows directly around and wets the battery cells and the electronic components of the battery module. Flow control elements are usually used to direct the cooling fluid specifically to the components of the battery module to be cooled.

Usually, such battery modules also contain printed circuit boards on which the above-mentioned electronic components are arranged.

However, the arrangement of both printed circuit boards and current guiding elements in a battery module occupies a relatively large amount of installation space in the battery module, leads to an increase in the weight and manufacturing costs of the battery module, and requires a high assembly effort.

### SUMMARY

It is an object of the present invention to create a flow guiding device which takes into account the problem explained above. In addition, the aim is to create a battery module that has a relatively low weight and can be manufactured with a relatively low assembly effort and with the lowest possible production costs.

According to the invention, this problem is solved by the objects of the independent claims. Advantageous embodiments are the subject of the dependent claims.

Accordingly, the basic idea of the invention is to form a flow guiding element on a base plate, on which an electronic component is also provided, which can be electrically connected to a battery module. Preferably, the base plate is designed as a printed circuit board on which electrically conductive tracks can be formed, which in turn can be electrically connected to said at least one electronic component. Thus, according to the invention, the flow guiding element can be used to direct a cooling fluid that can absorb waste heat from the battery module to cool it. In addition, the at least one electronic component can also be cooled by passing the cooling fluid past it in such a way that it can also absorb heat from the electronic component. The provision of a separate flow guiding device or a separate flow guiding element can thus be dispensed with.

The flow guiding device formed in this way requires less installation space compared to the individual components and has a lower weight, is easier to assemble in a battery module and thus also makes it possible to manufacture a battery module with lower production costs. In addition, a flow guiding device designed in this way achieves more efficient cooling of the electronic components arranged on it.

The flow guiding device for a battery module according to the invention, which serves to guide a cooling fluid, comprises a base plate, on the surface of which at least one electronic component for electrical connection to the battery module is arranged. The flow guiding device also has at least one flow guiding element projecting from the surface of the base plate, which at least partially limits a fluid path for the cooling fluid to flow through. The at least one electronic component may be, for example, an electrical or electronic switch, preferably a semiconductor switch, particularly preferably a transistor, a relay, an electrical resistor or impedance, a capacitor, particularly a condenser, an inductor, particularly a coil, a voltage or current transformer, or an.

Preferably, the at least one flow guiding element is integrally formed on the base plate or is connected thereto by a material bond. This embodiment has proven to be particularly mechanically resistant, space-saving and cost-effective.

According to an advantageous embodiment, the base plate is designed as a printed circuit board on which at least one electrical conductor track made of an electrically conductive material is present, which is electrically connected to the at least one electronic component. This eliminates the need for a separate printed circuit board with electrical conductive tracks, which takes up further installation space.

According to a further advantageous embodiment, the flow guiding element and the at least one electronic component are arranged on the base plate such that the at least one electronic component can be or is cooled by the cooling fluid flowing through the fluid path. This enables particularly simple and efficient cooling of the at least one electronic component by the cooling fluid provided for battery module cooling.

Advantageously, the at least one electronic component is arranged in or partially bounds the fluid path. In this way, the at least one electronic component can be cooled particularly effectively by the cooling fluid. In this case, the electronic component can assume the function of limiting the fluid path. In extreme cases, the electronic component can take over the function of a flow guiding element.

According to a preferred embodiment, the at least one electronic component is arranged in a region of the fluid path which has a flow density maximum when the cooling fluid flows through the fluid path. In this way, particularly efficient cooling of the electronic component is achieved.

According to another preferred embodiment, the base plate extends in a plate plane and the at least one flow guiding element extends substantially perpendicularly away from said plate plane. By means of this embodiment, a cooling fluid can be guided in a particularly effective and targeted manner.

According to a further preferred embodiment, the at least one flow guiding element is designed as a web projecting from the base plate. Also by means of this embodiment, a cooling fluid can be guided in a particularly effective and targeted manner.

Preferably, the at least one flow guiding element is ribbed. This embodiment is particularly easy and inexpensive to manufacture and also enables the cooling fluid to be guided in a particularly effective and targeted manner.

Particularly preferably, the base plate extends in a plate plane and, in a plan view along a direction perpendicular to the plate plane, the at least one flow guiding element is formed curved at least in sections. This embodiment is particularly easy and inexpensive to manufacture and also enables the cooling fluid to be guided in a particularly effective and targeted manner.

According to a preferred embodiment, the at least one electronic component is arranged in a region of the flow guiding device in which the at least one flow guiding element is curved. In this way, particularly efficient cooling of the electronic component is achieved.

According to a further preferred embodiment, the at least one flow guiding element is injection molded to the base plate. This embodiment is particularly easy and inexpensive to manufacture.

According to an advantageous embodiment, the material of the at least one flow guiding element and/or the base plate comprises or consists of a plastic. This embodiment is also particularly easy and inexpensive to manufacture.

Particularly preferably, the at least one flow guiding element is not the at least one electronic component.

The invention further relates to a battery module, in particular for a motor vehicle, having at least one battery cell and having a fluid path for guiding a cooling fluid for cooling the at least one battery cell. The battery module also includes a flow guiding device in accordance with the invention disposed in the fluid path. The advantages of the flow guiding device according to the invention explained above are thus also transferred to the battery module according to the invention.

Further important features and advantages of the invention are apparent from the dependent claims, from the drawings, and from the associated figure description based on the drawings.

It is understood that the features mentioned above and those to be explained below can be used not only in the combination indicated in each case, but also in other combinations or on their own, without leaving the scope of the present invention.

### BRIEF DESCRIPTION OF THE DRAWINGS

Preferred embodiments of the invention are shown in the drawings and will be explained in more detail in the following description, wherein identical reference signs refer to identical or similar or functionally identical components.

Showing, each schematically

FIG. 1 a first perspective view of an example of a flow guiding device according to the invention,

FIG. 2 a second perspective view of an example of a flow guiding device according to the invention,

### DETAILED DESCRIPTION

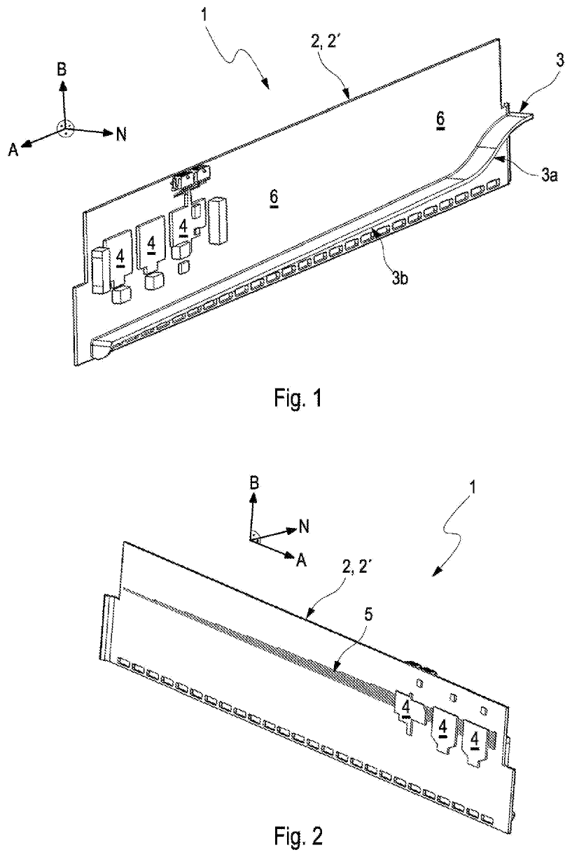

FIGS. 1 and 2 show a first and a second perspective view, respectively, of an example of a flow guiding device 1 according to the invention for guiding a cooling fluid for a battery module (not shown in FIGS. 1 and 2).

The flow guiding device 1 comprises a base plate 2, on the surface of which a plurality of electronic components 4 are arranged for electrical connection to the battery module. In this case, the electronic components 4 are applied to the base plate 2 by means of a suitable surface mounting technique known to the skilled person. The base plate 2 and the electronic components 4 partially define a fluid path 6 for the cooling fluid to flow through. The electronic components 4 may be, for example, switches, relays, resistors, capacitors, inductive components, voltage or current transformers, rectifiers or transistors.

In the example of FIGS. 1 and 2, the base plate 2 is formed as a printed circuit board 2′, on which a plurality of electrical conductive tracks 5 made of an electrically conductive material are present, which are connected to the electronic components 4. By means of the plurality of electrical conductive tracks 5, the flow guiding device 1 and in particular the electronic components 4 can be electrically connected to the battery module. In this case, the plurality of electrical conductive tracks 5 are injection molded, printed, dispensed or additively added to the printed circuit board 2′.

The printed circuit board 2′ extends in a board plane which is spanned by an extension direction A and extension direction B of the printed circuit board 2′. In the example of FIGS. 1 and 2, the direction of extension A extends perpendicular to the direction of extension B. In the example of FIGS. 1 and 2, the material of the printed circuit board 2′ is plastic.

The flow guiding device 1 also has a flow guiding element 3 protruding from the surface of the printed circuit board 2′, which partially delimits the fluid path 6. In this case, the flow guiding element 3 is injection-molded onto the printed circuit board 2′ and integrally formed thereon. The flow guiding element 3 is also designed as a web protruding from the printed circuit board 2′ and ribbed. In the example of FIGS. 1 and 2, the material of the flow guiding element 3 is made of the same plastic as the plastic of the material of the printed circuit board 2′.

The flow guiding element 3 also extends along a direction N perpendicular to the direction of extension A and the direction of extension B away from the plate plane of the printed circuit board 2′.

In a plan view along this direction N, the flow guiding member 3 is curved along a flow guiding member section 3a and straight along a flow guiding member section 3b. It is conceivable that the flow guiding element 3 has several curved flow guiding element sections or also has alternating left-curved and right-curved flow guiding element sections, wherein a left-curved flow guiding element section merges into a right-curved flow guiding element section at a turning point or vice versa. It is also conceivable that straight formed and curved formed flow guiding element sections alternate along an extension direction of the flow guiding element 3. It is also conceivable that the lengths of a curved-shaped flow guiding member section and a straight-shaped flow guiding member section along an extending direction of the flow guiding member 3 are in a ratio of between 1 to 1 to 1 to 10 with respect to each other.

In the example of FIGS. 1 and 2, the lengths of the flow guiding element 3 and the printed circuit board 2′ have a ratio of 1 to 1. However, it is also conceivable that the lengths of the flow guiding element 3 and the printed circuit board 2′ are in a ratio of up to 1 to 10 to each other.

The flow guiding element 3 and the electronic components 4 are arranged on the printed circuit board 2′ in such a way that the electronic components 4 can be cooled by the cooling fluid flowing through the fluid path 6. The flow guiding element 3 is thereby different from the electronic components 4.

In an alternative variant to the example of FIGS. 1 and 2, an electronic component can be arranged in a region of the fluid path 6 which has a flow density maximum when the cooling fluid flows through the fluid path 6. It is also conceivable that an electronic component is arranged in an area of the flow guiding device 1 in which the flow guiding element 3 is curved. In the example of FIGS. 1 and 2, such an area is arranged along the extension direction B adjacent to the curved flow guiding element section 3a of the flow guiding element 3.

A flow guiding device 1 presented previously may be arranged in a battery module fluid path (not shown in FIGS. 1 and 2) of the battery module, so that the cooling fluid is directed by means of the flow guiding device 1 to cool one or more battery cells of the battery module. It is conceivable that several flow guiding devices 1 are arranged in the battery module, in particular at a distance from each other.

1. A flow guiding device for guiding a cooling fluid for a battery module, comprising:
a base plate including a surface;
at least one electronic component arranged on the surface of the base plate and configured for electrical connection to the battery module; and
at least one flow guiding element projecting from the surface of the base plate, the at least one flow guiding element at least partially delimits a fluid path for the cooling fluid to flow through.

2. The flow guiding device according to claim 1, wherein the at least one flow guiding element is integrally formed on the base plate or is connected thereto by a material bond.

3. The flow guiding device according to claim 1, wherein:
the base plate is designed as a printed circuit board;
at least one electrical conductor track made of an electrically conductive material is arranged on the printed circuit board; and
the at least one electrical conductor track is electrically connected to the at least one electronic component.

4. The flow guiding device according to claim 1, wherein the at least one flow guiding element and the at least one electronic component are arranged on the base plate such that the at least one electronic component can be cooled or is cooled by the cooling fluid flowing through the fluid path.

5. The flow guiding device according to claim 1, wherein the at least one electronic component is arranged in the fluid path or partially bounds the fluid path.

6. The flow guiding device according to claim 1, wherein the at least one electronic component is arranged in a region of the fluid path which has a flow density maximum when the cooling fluid flows through the fluid path.

7. The flow guiding device according to claim 1, wherein the base plate extends in a plate plane and the at least one flow guiding element extends substantially perpendicularly away from the plate plane.

8. The flow guiding device according to claim 1, wherein the at least one flow guiding element is designed as a web projecting from the base plate.

9. The flow guiding device according to claim 1, wherein the at least one flow guiding element is ribbed.

10. The flow guiding device according to claim 1, wherein the base plate extends in a plate plane and, in a plan view along a direction perpendicular to the plate plane, the at least one flow guiding element is curved at least in sections.

11. The flow guiding device according to claim 1, wherein the at least one electronic component is arranged in a region of the flow guiding device in which the at least one flow guiding element is curved.

12. The flow guiding device according to claim 1, wherein the at least one flow guiding element is injection-molded to the base plate.

13. The flow guiding device according to claim 1, wherein the at least one flow guiding element and/or the base plate comprise a plastic material.

14. A battery module for a motor vehicle, comprising:
at least one battery cell;
a fluid path for guiding a cooling fluid for cooling the at least one battery cell; and
at least one flow guiding device arranged in the fluid path according to claim 1.

15. The battery module according to claim 14, wherein the at least one flow guiding element of the at least one flow guiding device is integrally formed on the base plate of the at least one flow guiding device.

16. The battery module according to claim 14, wherein the base plate of the at least one flow guiding device includes a printed circuit board.

17. The battery module according to claim 16, wherein at least one electrical conductor track is arranged on the printed circuit board.

18. The battery module according to claim 17, wherein the at least one electrical conductor track is electrically connected to the at least one electrical component of the at least one flow guiding device.

19. The battery module according to claim 14, wherein the at least one flow guiding element and the at least one electronic component are arranged on the base plate such that the at least one electronic component can be cooled or is cooled by the cooling fluid flowing through the fluid path.

20. The battery module according to claim 14, wherein the at least one electronic component is arranged in the fluid path or partially bounds the fluid path.
